(19) United States
(12) Patent Application Publication
(10) Pub. No.: US 2007/0136640 A1
(43) Pub. Date: Jun. 14, 2007

(54) Defect detection and repair in an embedded random access memory

(76) Inventor: Anis M. Jarrar, Austin, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/300,078

(22) Filed: Dec. 14, 2005

(51) Int. Cl. G11C 29/00

(52) U.S. Cl. 714/763; 714/718

(57) ABSTRACT

An integrated circuit comprises a volatile memory array, a non-volatile memory array, a plurality of registers, and a plurality of flip-flops. A portion of the non-volatile memory array is used for storing an address of a defective memory cell of the volatile memory array. The plurality of registers is coupled to the non-volatile memory array. The plurality of registers temporarily stores the address of the defective memory cell during a normal operating mode of the integrated circuit. Each of the plurality of flip-flops are used for substituting for a defective memory cell of the volatile memory array and are implemented on the integrated circuit physically separate from the volatile memory array.

### FIELD OF THE INVENTION

This invention relates generally to random access memories, and more particularly to defect detection and repair of a random access memory embedded in a data processor.

### BACKGROUND OF THE INVENTION

Redundancy may be used in an integrated circuit random access memory (RAM) to cure, or repair, manufacturing defects by replacing rows or columns having defects with spare rows or columns. In order to repair a defective row or column, the defective row or column is deselected and a redundant row or column is assigned in its place by blowing a plurality of fusible links. The fusible links are used to store the address of the defective row or column and is typically blown using a high-energy laser, or may be blown electrically at probe test. The ability to repair a memory that has only a few defective rows or columns can result in substantially increased manufacturing yields. Redundancy may not be used in some embedded memories because the embedded memories may not be directly accessible.

Error correction codes (ECC) have been used to detect and correct single-bit errors and to detect, but not correct, multi-bit errors in memory arrays. The single-bit errors and multi-bit errors may be due to soft errors in the memory array. A soft error in a particular bit may be due to, for example, exposure to temperature extremes, alpha particle emissions, or long term usage. The ECC can correct single-bit errors without the use of additional redundant bits, but multi-bit errors typically cannot be corrected in the field even if the memory includes unused redundant rows or columns.

Therefore, there is a need for a memory that can repair ECC detected multi-bit errors.

### BRIEF DESCRIPTION OF THE DRAWINGS

The foregoing and further and more specific objects and advantages of the instant invention will become readily apparent to those skilled in the art from the following detailed description of a preferred embodiment thereof taken in conjunction with the following drawings:

FIG. 1 illustrates, in block diagram form, a data processor in accordance with an embodiment of the present invention.

FIG. 2 illustrates a flow chart of a method for repairing defective memory cells of a volatile memory array in a data processor.

### DETAILED DESCRIPTION

Generally, the present invention provides a circuit and method for repairing defective memory cells in a volatile memory array of a data processor. Error correction codes are used to detect errors in the data stored in the memory array. The errors in the data indicate defective memory cells of a volatile memory array. In a typical ECC protocol, if a detected error is a single-bit error, the ECC can apply a correction. If an error is a multi-bit error, the ECC can detect the error but not correct it. The multi-bit errors in the volatile memory array detected by the ECC are corrected using a portion of a non-volatile memory array to store the addresses of the defective cells. During initial operation of the data processor as it exits a reset state, the addresses of the defective cells are loaded into a plurality of registers for storing the address of the defective memory cell during a normal operating mode of the integrated circuit. A plurality of flip-flops is used as needed to substitute for defective memory cells. The plurality of flip-flops is implemented on the integrated circuit physically separate from the volatile memory array using standard cell logic.

The circuit and method can be used to repair defective memory cells during manufacturing or can be used to increase reliability or fault tolerance in the field. The plurality of flip-flops is guaranteed to be defect free because they are structurally tested using scan testing during the manufacturing process. Also, the circuit and method can augment ECC by allowing multi-bit errors to be detected and repaired.

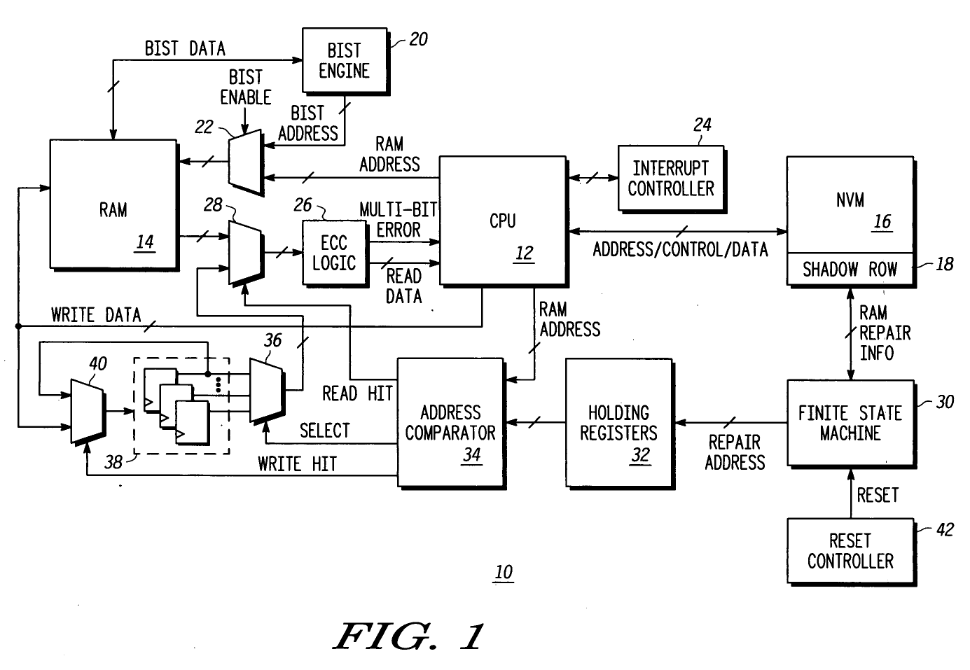

FIG. 1 illustrates, in block diagram form, a data processor 10 in accordance with an embodiment of the present invention. Data processor 10 includes central processing unit (CPU) 12, random access memory (RAM) 14, non-volatile memory (NVM) 16, built-in self test (BIST) engine 20, multiplexers 22, 28, 36, and 40, interrupt controller 24, error correction code (ECC) logic 26, finite state machine 30, holding registers 32, address comparator 34, plurality of flip-flops 38, and reset controller 42. In the illustrated embodiment, RAM 14 is an embedded conventional static random access memory (SRAM). In other embodiments; RAM 14 can be another type of memory such as a dynamic random access memory (DRAM). RAM 14 receives address information, labeled “RAM ADDRESS” and write data labeled “WRITE DATA” from CPU 12. CPU 12 may be one of several co-processors (not shown) in data processor 10 that is capable of functioning as a bus master. In other embodiments, RAM 14 may be externally accessible via an input/output (I/O) port (not shown). RAM 14 includes a plurality of memory cells organized in row and columns. A row of memory cells includes a word line and all of the memory cells coupled to the word line. A column of memory cells includes a bit line, or bit line pair, and all of the memory cells coupled to the bit line. Note that RAM 14 also includes row and column decoders, sense amplifiers, and other peripheral circuitry used to access RAM 14 that is not shown.

Data processor 10 includes a BIST circuit for functionally testing RAM 14. The BIST circuit writes a test pattern to RAM 14 and then reads RAM 14 to detect if the memory cells of RAM 14 output the expected data. The BIST circuit includes BIST engine 20 and multiplexer 22. Multiplexer 22 has a first input coupled to CPU 12 for receiving address RAM ADDRESS, a second input coupled to CPU 12 for receiving an address labeled “BIST ADDRESS”, an output coupled to RAM 14, and a control terminal coupled to BIST engine 20 for receiving a control signal labeled “BIST ENABLE”. BIST engine 20 also has a terminal coupled to RAM 14 for providing and receiving data signals labeled “BIST DATA”.

Read data from RAM 14 is provided to CPU 12 via ECC logic 26. In the illustrated embodiment, ECC logic 26 runs a conventional ECC protocol that can detect and repair single bit errors and detect but not repair multi-bit errors. ECC logic 26 has an input coupled to multiplexer 28, an output coupled to CPU 12 for reporting a multi-bit error, and another output coupled to CPU 12 for providing data labeled “READ DATA”. Multiplexer 28 receives read data from either RAM 14 or from the plurality of flip-flops 38 via multiplexer 36. ECC input data is provided by flip-flops 38 if one or more of flip-flops 38 have been used to repair addressed defective cells of RAM 14.

Write data labeled “WRITE DATA” is provided by CPU 12 to both of multiplexer 40 and RAM 14. If one or more of the addressed memory cells of RAM 14 have been repaired, then the WRITE DATA is provided to one of flip flops 38, otherwise, the WRITE DATA is written to the regular memory cells of RAM 14. The read and write operations of RAM 14 will be discussed in more detail below. Note that the plurality of flip-flops 38 comprises D-type flip-flops in the illustrated embodiment. The D-type flip-flops may be implemented as “standard cell logic” in a conventional integrated circuit manufacturing process such as a CMOS (complementary metal-oxide semiconductor) process. This provides an advantage of being highly reliable and relatively easy to test as compared to an embedded RAM such as RAM 14. In other embodiments, the plurality of D-type flip-flops 38 may comprise a different type of flip-flop.

CPU 12 is bi-directionally coupled to interrupt controller 24. Interrupt controller 24 may also be referred to as an interrupt handler, and can be implemented as hardware, software, or a combination of hardware and software. CPU 12 is also bi-directionally coupled to NVM 16 to transmit signals labeled “ADDRESS/CONTROL/DATA”. In the illustrated embodiment, NVM 16 includes a plurality of flash non-volatile memory cells organized in rows and columns. Also included in NVM 16 but not shown are row and column decoders, sense amplifiers, and other access circuitry. In other embodiments, NVM 16 may be another type of non-volatile memory, such as for example, an EEPROM (electrically programmable and erasable read only memory), or a MRAM (magnetic random access memory). NVM 16 also includes a shadow row 18. Shadow row 18 is one or more specially designated rows for storing test, manufacturing, or identifying information about the integrated circuit implementing data processor 10. In the illustrated embodiment, shadow row 18 is not visible to or accessible by a user of the data processor 10. The shadow row 18 is bi-directionally coupled to finite state machine 30 for transmitting and receiving information labeled “RAM REPAIR INFO”. Finite state machine also has an input for receiving a reset signal labeled “RESET” from reset controller 42, and a plurality of outputs for providing signals labeled “REPAIR ADDRESS” to holding registers 32. Reset controller may be responsive to any one or all of CPU 12, interrupt controller 24, or another component of data processor 10. Data processor 10 may also include components not illustrated in FIG. 1, such as for example, additional memory, additional processors, special purpose modules, analog circuits, and the like.

Holding registers 32 is a plurality of conventional registers for storing the addresses of repaired memory cells of RAM 14. Holding registers 32 has an output coupled to a first input of address comparator 34. Address comparator 34 has a second input coupled to CPU 12 for receiving address signals labeled “RAM ADDRESS”, a first output for providing a hit signal labeled “READ HIT” to a control terminal of multiplexer 28, a second output for providing a select signal labeled “SELECT” to a control terminal of multiplexer 36, and a third output for providing a hit signal labeled “WRITE HIT” to a control terminal of multiplexer 40.

In operation, CPU 12 executes instructions that require data to be read from and written to RAM 14. ECC logic 26 analyses read data from RAM 14 and if a single-bit error is detected, ECC logic 26 corrects the error. In the case where a multi-bit error is detected, ECC logic 26 provides a signal to CPU 12 labeled “MULTI-BIT ERROR”. The error may be, for example, a soft error caused by exposure to temperature extremes or from prolonged usage. In response to the signal MULTI-BIT ERROR, an interrupt is generated by interrupt controller 24. The failing address or addresses are programmed into shadow row 18 of NVM 16. Also, one or more flip-flops of the plurality of flip-flops 38 are designated to replace the defective memory location of RAM 14 using, for example, BIST engine 20. In addition, the interrupt causes reset controller 42 to provide reset signal RESET to finite state machine 30 and to the entire data processor. The finite state machine 30 retrieves the address of the defective location of RAM 14, and causes the address to be stored in holding registers 32. Each time the data processor 10 is reset or restarted, the finite state machine loads the defective addresses from shadow row 18 to holding registers 32. Note that the defective memory locations may also be detected during BIST testing.

During a read operation of RAM 14 after RAM 14 has been repaired, a RAM ADDRESS is provided to RAM 14 via multiplexer 22 and to address comparator 34. Address comparator 34 compares the RAM ADDRESS to addresses stored in holding registers 32. If the RAM ADDRESS matches an address in holding registers 32, then a SELECT signal is provided to multiplexer 36 to select the correct flip-flop of flip-flops 38 to read. Address comparator 34 also provides a READ HIT signal to multiplexer 28 to select the input coupled to the output of multiplexer 36 to provide the input to ECC logic 26, whose output is the READ DATA to CPU 12. If the RAM ADDRESS does not match one of the addresses stored in holding registers 32, then the READ HIT signal is not asserted and READ DATA is provided to CPU 12 from RAM 14 via multiplexer 28 and ECC logic 26.

During a write operation of RAM 14 after RAM 14 has been repaired, a RAM ADDRESS is provided to RAM 14 and to address comparator 34. If there is a match, indicating that the RAM ADDRESS is to a location of RAM 14 that has been repaired, then address comparator provides a WRITE HIT signal to multiplexer 40 to allow the WRITE DATA to be provided to one of the plurality of flip-flops 38. If the RAM ADDRESS does not match one of the addresses stored in holding registers 32, then the WRITE HIT signal is not asserted and the WRITE DATA is provided from CPU 12 to RAM 14.

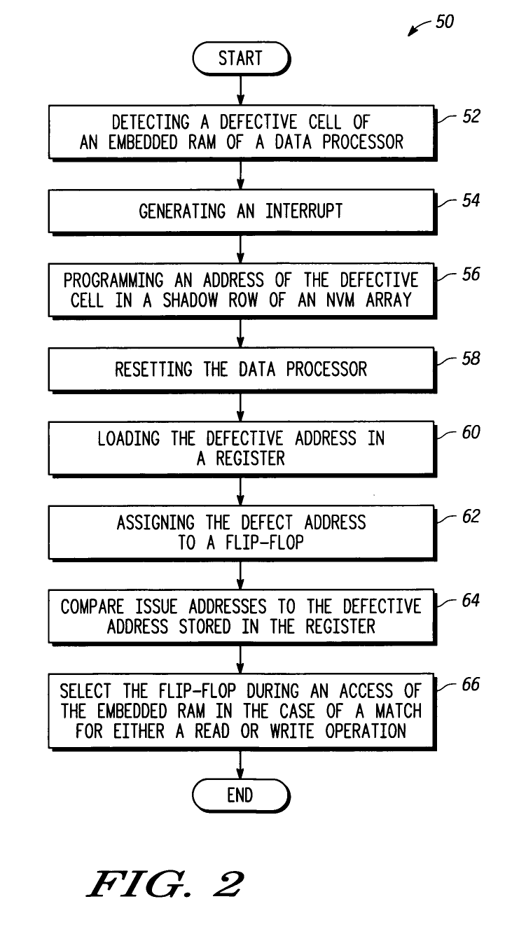

FIG. 2 illustrates a flow chart 50 of a method for repairing defective memory cells of volatile memory 14 in a data processor 10. At step 52 a defective memory cell of the volatile memory 14 is detected. The defective cell may have been detected using ECC logic 26 or BIST engine 20. At step 54 an interrupt is generated by interrupt controller 24 and provided to CPU 12. The interrupt ends the execution of instructions by CPU 12 and starts the process of repairing the defective memory location. At step 56, in response to the interrupt, the address of the defective memory cell is programmed into a portion of a nonvolatile memory array in response to the interrupt. In the illustrated embodiment, the portion is the shadow row 18 of NVM 16. At step 58, the data processor is reset to an initial state in response to the interrupt. At step 60, the address of the defective memory cell is loaded into a register of holding registers 32. At step 62, a flip-flop of a plurality of flip-flops 38 is assigned to substitute for the defective memory cell. The data processor then executes instructions during a normal operating mode. In the course of executing instructions, the CPU 12 accesses RAM 14. During read or a write accesses, the addresses are provided to address comparator 34 and address comparator 34 compares the addresses to the defective addresses stored in holding register 32 as indicated at step 64. In the case of a match, a hit signal is provided by address comparator 34 to select the assigned flip-flop of flip-flops 38.

While the invention has been described in the context of a preferred embodiment, it will be apparent to those skilled in the art that the present invention may be modified in numerous ways and may assume many embodiments other than that specifically set out and described above. Accordingly, it is intended by the appended claims to cover all modifications of the invention which fall within the true scope of the invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. An integrated circuit comprising:
a volatile memory array;
a non-volatile memory array, a portion of the non-volatile memory array for storing an address of a defective memory cell of the volatile memory array;
a plurality of registers, coupled to the non-volatile memory array, the plurality of registers for temporarily storing the address of the defective memory cell during a normal operating mode of the integrated circuit; and
a plurality of flip-flops, each of the plurality of flip-flops for substituting for a defective memory cell of the volatile memory array, wherein the plurality of flip-flops are implemented on the integrated circuit physically separate from the volatile memory array.

2. The integrated circuit of claim 1, wherein the defective memory cell is detected using one of either error correction codes (ECC) or built-in self test (BIST).

3. The integrated circuit of claim 1, wherein the plurality of flip-flops are D-type flip-flops.

4. The integrated circuit of claim 1, wherein the portion of the non-volatile memory array is characterized as being one or more shadow rows that are not accessible by a bus master during normal operation of the integrated circuit.

5. The integrated circuit of claim 1, further comprising a comparator coupled to a bus master and to the plurality of registers, the comparator for comparing addresses provided by the bus master for accessing the volatile memory array to addresses stored in the plurality of registers, and in response to determining a match, causing the plurality of flip-flops to be accessed instead of the memory array.

6. The integrated circuit of claim 1, further comprising a finite state machine coupled between the portion of the non-volatile memory array and the plurality of registers, the finite state machine for reading the portion of the non-volatile memory array and for loading the plurality of registers with addresses of defective memory cells of the volatile memory array.

7. The integrated circuit of claim 1, wherein the portion of the non-volatile memory array is programmed with the address of the defective memory cell during a built-in self test (BIST) of the volatile memory array.

8. The integrated circuit of claim 1, wherein the volatile memory array comprises a plurality of static random access memory cells.

9. A data processor comprising:
a bus master;
a volatile memory array coupled to the bus master;
test logic for detecting defective memory cells in the volatile memory array;
a non-volatile memory array coupled to the bus master, a portion of the non-volatile memory array for storing an address of a defective memory cell of the volatile memory array;
a plurality of registers, coupled to the non-volatile memory array, the plurality of registers for temporarily storing the address of the defective memory cell during a normal operating mode of the integrated circuit; and
a plurality of flip-flops, each of the plurality of flip-flops for substituting for a defective memory cell of the volatile memory array, wherein the plurality of flip-flops are implemented on the integrated circuit physically separate from the volatile memory array; and
a comparator coupled to the bus master and to the plurality of registers, the comparator for comparing addresses from the bus master to the address of the defective memory cell, and in response to a match, the comparator for selecting a flip-flop of the plurality of flip-flops to substitute for the defective memory cell.

10. The data processor of claim 9, wherein the defective memory cell is detected using one of either error correction codes (ECC) or built-in self test (BIST).

11. The integrated circuit of claim 9, wherein the plurality of flip-flops are D-type flip-flops.

12. The integrated circuit of claim 9, wherein the portion of the non-volatile memory array is characterized as being one or more shadow rows that are not accessible by a bus master during normal operation of the integrated circuit.

13. The integrated circuit of claim 9, further comprising a finite state machine coupled between the portion of the non-volatile memory array and the plurality of registers, the finite state machine for reading the portion of the non-volatile memory array and for loading the plurality of registers with addresses of defective memory cells of the volatile memory array.

14. The integrated circuit of claim 9, wherein the portion of the non-volatile memory array is programmed with the address of the defective memory cell during a built-in self test (BIST) of the volatile memory array.

15. A method for repairing defective memory cells of a volatile memory array in a data processor, comprising:
detecting a defective memory cell of the volatile memory array;
generating an interrupt to a bus master of the data processor;
programming an address of the defective memory cell into a portion of a nonvolatile memory array in response to the interrupt;
resetting the data processor to an initial state in response to the interrupt;
loading the address of the defective memory cell into a register; and
assigning a flip-flop of a plurality of flip-flops to substitute for the defective memory cell.

16. The method of claim 15, further comprising:
comparing the address of the defective memory cell to memory array addresses provided by the bus master; and
selecting the flip-flop during a volatile memory array access in response to the address of the defective memory cell matching an address of the memory array addresses provided by the bus master.

17. The method of claim 15, wherein detecting a defective memory cell of the volatile memory array further comprises detecting a defective memory cell using error correction codes (ECC).

18. The method of claim 15, wherein the plurality of flip-flops are implemented separately from the volatile memory array.

19. The method of claim 15, wherein programming an address of the defective memory cell into a portion of a non-volatile memory array further comprises programming an address of the defective memory cell into a portion of the non-volatile that is not accessible of the bus master during normal operation of the data processor.

20. The method of claim 15, wherein the volatile memory array is characterized as being a static random access memory.
